(19) United States
(12) Patent Application Publication
(10) Pub. No.: US 2008/0297168 A1
(43) Pub. Date: Dec. 4, 2008

(54) Methods and apparatus for testing one or more differential signaling channels for opens

(76) Inventor: Kenneth P. Parker, Fort Collins, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/011,938

(22) Filed: Jan. 30, 2008

(30) Foreign Application Priority Data
May 31, 2007 (CN) 200710108610.3

(51) Int. Cl. G01R 31/04

(52) U.S. Cl. 324/538

(57) ABSTRACT

In one embodiment, a method for testing a differential signaling channel having a differential pair of signal paths, and a pair of signal grounds bounding the differential pair, includes: causing positive and negative phases of a differential waveform to be driven over respective paths of the differential pair while monitoring a signal induced in a capacitive sense plate positioned adjacent to, and capacitively coupled to, all of the paths and grounds of the channel; when an amplitude of the monitored signal is within a first range, indicating to a user that there are no open defects in the differential signaling channel; and when the amplitude of the monitored signal falls within one or more second ranges, and not within the first range, indicating to the user that an open exists in the differential signaling channel. Other embodiments are also disclosed.

### PRIORITY CLAIM

This patent application claims the benefit of pending Chinese Patent Application Serial Number 200710108610.3, filed May 31, 2007, by Kenneth P. Parker for METHODS AND APPARATUS FOR TESTING ONE OR MORE DIFFERENTIAL SIGNALING CHANNELS FOR OPENS, which patent application is hereby incorporated herein.

### BACKGROUND

In modern, high-speed circuit designs, there is significant growth in the use of differential signaling channels to route signals between the different components (e.g., integrated circuits) of circuit assemblies (e.g., printed circuit boards or Multi-Chip Modules). Using differential signaling technology, a single signal is transmitted over a differential pair of signal paths (e.g., a pair of matched wires having controlled impedances and nearly identical lengths), between a differential driver and a differential receiver. At the driving end of the channel, the differential driver transmits an intended signal over one of the signal paths, and transmits the signal's complement over the other signal path. At the receiving end of the channel, the differential receiver subtracts the complementary signal from the intended signal, yielding a signal that has twice the amplitude of the intended signal.

One advantage provided by differential signaling technology is greater noise immunity. For example, if a time varying signal S(t) is transmitted over one signal path of a differential signaling channel, and a time varying signal −S(t) is transmitted over the other signal path of the channel, then any noise N(t) imparted to both of the signal paths will be removed from the signal R(t) output from a differential receiver (i.e., R(t)=[S(t)+N(t)−[−S(t)+N(t)], which simplifies to R(t)=2*S(t)).

In the past, capacitive testing has sometimes been used to test differential signaling channels for opens. Capacitive testing is described, in general, in the United States patents of Crook et al (U.S. Pat. No. 5,557,209), Kerschner (U.S. Pat. No. 5,420,500) and Kerschner et al (U.S. Pat. No. 5,498,964). An exemplary setup and equivalent circuit for capacitively testing a differential signaling channel are shown in FIGS. 1 & 2 (and briefly described below).

By way of example, the circuit assembly 100 shown in FIG. 1 comprises an integrated circuit (IC) 102 and a connector 104, both of which are mounted on a printed circuit board (PCB) 106. A differential signaling channel 108 comprised of first and second signal paths 110, 112 couples pins of the IC 102 to pins of the connector 104. For ease of viewing, the paths 110, 112 are shown to be of different lengths, and are routed on different layers of the PCB 106. However, in reality, the paths 110, 112 will likely be of matched lengths and will be routed side-by-side in a single layer of the PCB 106.

The connector 104 is soldered to the PCB 106 via a plurality of solder balls 114. However, the solder ball intended to couple the connector 104 to the signal path 112 is missing, thereby creating an “open” defect. The open introduces a series capacitance C_{O} in the signal path 112.

Positioned above the connector 104 is a capacitive sense plate 116. As shown, the sense plate 116 may be placed directly in or above the connector 104, thereby creating a small capacitance C_{S} between the sense plate 116 and each contact of the connector 104. Alternately, an integrated circuit or other component having engineered capacitances C_{S} may be inserted in the connector 104, and the sense plate 116 may be positioned on this component. The sense plate 116 is connected to a buffer 118, which is in turn connected to an alternating current (AC) signal detector 120. When testing the signal path 112 for opens, a first test probe 122 is used to couple the signal path 112 to an AC source 124, and one or more other test probes 126 are used to couple the signal path 110 and other nodes of the circuit assembly 100 to ground.

FIG. 2 illustrates an equivalent circuit for the apparatus shown in FIG. 1. The switch, S, represents the quality of the signal path 112 being tested. If the signal path 112, including the solder ball that couples the signal 112 to the connector 104, is defect-free (i.e., there are no opens in the path 112), then the switch S is closed, and the capacitance seen by the AC signal detector 120 is Cₛ. However, if the path 112 has an open, switch S in the equivalent circuit is also open, and the capacitance seen by the AC signal detector 120 is C_{S}*C_{O}/(C_{S}+C_{O}). If C_{S} is chosen to be significantly larger than any possible C_{O}, an open in a signal path will result in the AC signal detector 120 seeing a capacitance near C_{O}. As a result, the AC signal detector 120 must have sufficient resolution to distinguish C_{S} from C_{O}.

After testing signal path 112 as described above, the stimulus and grounding of the signal paths 110, 112 can be swapped, and signal path 110 may be tested for opens similarly to how signal path 112 is tested for opens. Further details on how capacitive testing might be performed via a connector mounted on a substrate are disclosed in the United States patents of Parker et al (U.S. Pat. No. 6,933,730) and Parker et al (U.S. Pat. No. 6,960,917).

Although the setup shown in FIG. 1 provides an acceptable means for testing “probe-able” signal paths of a differential signaling channel, printed circuit boards are becoming more densely populated with devices, and the ability to place test probes in contact with board-level nodes is becoming more difficult. In some cases, this is because a test probe is simply too large compared to the pitch or density of board-level nodes. In other cases, a board-level node is not even provided. Another problem presented by current PCB topologies is that there are times when the number of nodes that need to be probed exceeds the number of available test probes. As a result, new techniques for testing these boards (and particularly, the differential signaling channels of these boards) are needed.

### BRIEF DESCRIPTION OF THE DRAWINGS

Illustrative embodiments of the invention are illustrated in the drawings, in which:

FIG. 1 illustrates an exemplary setup for capacitively testing a differential signaling channel;

FIG. 2 illustrates an equivalent circuit for the apparatus shown in FIG. 1;

FIG. 3 illustrates an exemplary differential signaling channel, coupled between a differential driver and a connector;

FIG. 4 illustrates an exemplary differential signaling channel, coupled between a differential driver and a differential receiver;

FIG. 5 illustrates how the signal grounds shown in FIGS. 3 & 4 could take the form of ground paths;

FIG. 6 illustrates how capacitive testing might be used to test a defect-free differential signaling channel;

FIG. 7 illustrates an equivalent circuit for the apparatus shown in FIG. 6;

FIG. 8 illustrates how capacitive testing might be used to test a differential signaling channel having an open defect in the signal path carrying the negative phase of a differential waveform;

FIG. 9 illustrates an equivalent circuit for the apparatus shown in FIG. 8;

FIG. 10 shows a graph of “F” versus ratios of C_{C} to C_{O} ranging from roughly 0.1 to 30;

FIG. 11 illustrates a table of expected sense plate signals for various open defects in a differential signaling channel;

FIG. 12 illustrates how capacitive testing might be used to test a differential signaling channel having an open defect in the signal ground adjacent the signal path carrying the negative phase of a differential waveform;

FIG. 13 illustrates an equivalent circuit for the apparatus shown in FIG. 12;

FIG. 14 illustrates how capacitive testing might be used to test a differential signaling channel for opens and some shorts;

FIG. 15 illustrates an exemplary method for testing a differential signaling channel;

FIG. 16 illustrates an exemplary method for testing a plurality of differential signaling channels in parallel; and

FIG. 17 illustrates exemplary apparatus for executing the method 1500 or 1600.

### DETAILED DESCRIPTION

As a preliminary manner, it is noted that, in the following description, like reference numbers appearing in different drawing figures refer to like elements/features. Often, therefore, like elements/features that appear in different drawing figures will not be described in detail with respect to each of the drawing figures.

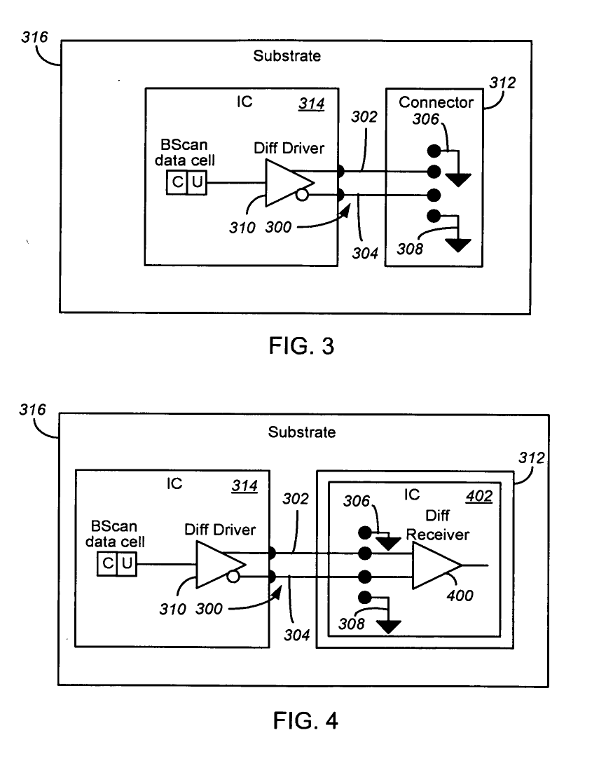

Before describing novel methods and apparatus for testing differential signaling channels for open defects, some exemplary differential signaling channels will be described. In this regard, FIGS. 3 & 4 illustrate two exemplary configurations of a differential signaling channel 300. The channel 300 includes a differential pair of signal paths 302, 304 bounded by a pair of signal grounds 306, 308. The signal grounds 306, 308 help to isolate the signal paths 302, 304 from noise-inducing sources (including other signal paths). Typically, each of the signal paths 302, 304 will be coupled between a differential driver 310 at one end, and a connector 312 (FIG. 3) or differential receiver 400 (FIG. 4) at the other end.

The differential driver 310 will typically be provided in an integrated circuit 318, although it need not. For example, the differential driver 310 could be provided as a discrete component on the substrate 320. In some cases, the integrated circuit 318 (or other component providing the differential driver 310) may be coupled to the substrate 320 via a second connector.

FIG. 3 illustrates a coupling of the differential signaling channel 300 between a differential driver 310 and a connector 312. The connector 312 may take many forms, including those of an edge connector (e.g., for coupling to a PCB), a socket (e.g., for receiving an integrated circuit), or a cable connector. In some cases, the connector 312 may receive a component carrying a differential receiver 400, and in other cases, the connector 312 may receive a component for extending the length of the differential signaling channel 300.

FIG. 4 illustrates a coupling of the differential signaling channel 300 between a differential driver 310 and a differential receiver 400. By way of example, the differential receiver 400 may be provided in an integrated circuit 402 seated in the connector 312. However, in other embodiments, the differential receiver could be provided in a component other than an integrated circuit, or the integrated circuit 402 or other component could be coupled to the substrate 320 without using the connector 312.

The substrate 320 may take various forms, including those of a PCB or flex circuit.

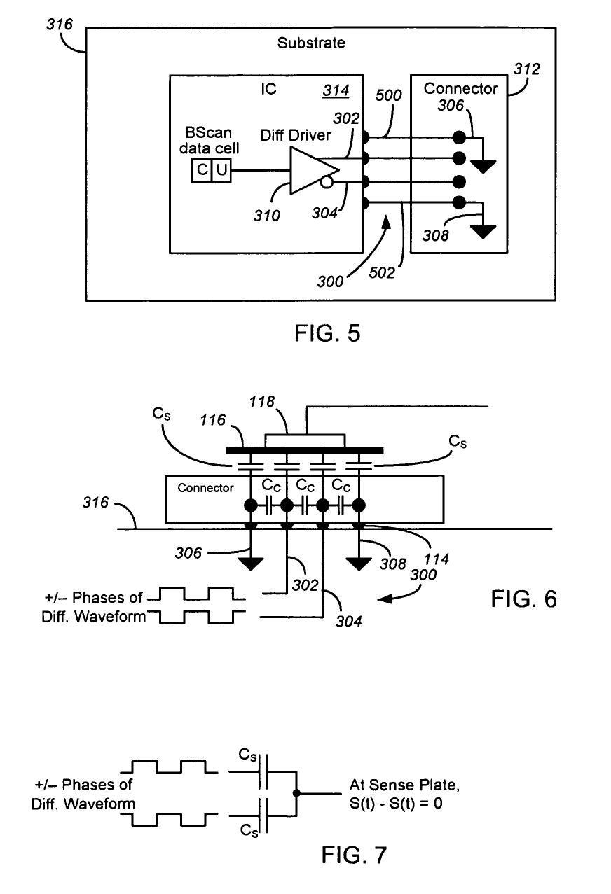

In FIGS. 3 & 4, the signal grounds 306, 308 are shown as ground points (e.g., grounded pins of the connector 312) adjacent the ends of the signal paths 302, 304. In other embodiments (FIG. 5), the signal grounds 306, 308 could take the form of ground paths 500, 502 extending along part or all of the lengths of the signal paths 302, 304. If the signal grounds take the form of ground paths 500, 502, all of the paths 302, 304, 500, 502 will typically be formed in the same layer of the substrate 320, although it is possible that the paths 302, 304, 500, 502 could be implemented in a stacked configuration (i.e., where each path 302, 304, 500, 502 is formed in a different layer of the substrate 320) or in a configuration where the ground paths 500, 502 are formed above or below a layer in which the signal paths 302, 304 are formed.

Having described various exemplary configurations of a differential signaling channel 300, methods and apparatus for testing one or more differential signaling channels will now be described.

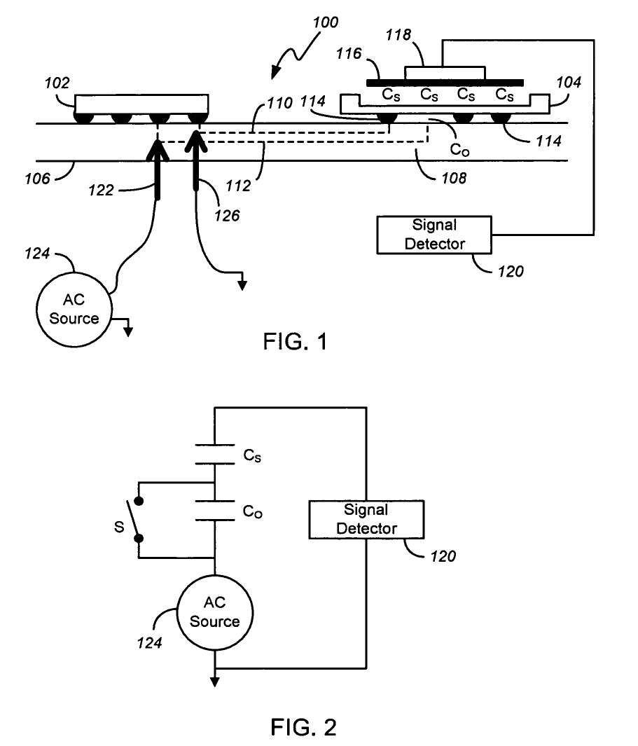

One way to test a differential signaling channel for opens is by means of a capacitive test system, such as the capacitive test system shown in FIG. 1. In the past, this has been done by applying a stimulus to one signal path 302 while simultaneously: 1) grounding the other signal path 304, and 2) monitoring a signal induced in a capacitive sense plate 116 positioned in or adjacent an integrated circuit 402 or connector 312 at which the channel 300 terminates. A stimulus is then applied to the other signal path 304 while simultaneously: 1) grounding the first signal path 302, and 2) monitoring a signal induced in the capacitive sense plate 116.

In the past, the differential driver 310 to which a channel 300 is connected has not been employed to stimulate the signal paths 302, 304 of the channel 300. In fact, when applying a stimulus to one signal path at a time, as described above, the differential driver 310 ha not even been powered up. However, powering the differential driver 310 and stimulating both signal paths 302, 304 in parallel provides a useful way to test the channel 300, as will be described below.

FIGS. 6 & 7 illustrate a defect-free case. Here, a small capacitance C_{S} is formed between the sense plate 116 and each of the signal paths and grounds of the differential signaling channel 300. See, FIG. 6. Another small capacitance, C_{C} is formed between adjacent contacts of the connector 312 or integrated circuit 402 at which the differential signaling channel 300 terminates. If the sense plate 116 is properly positioned, the capacitances C_{S} should be substantially equal (i.e., equal but for small manufacturing or positioning tolerances). Similarly, if the connector 312 or integrated circuit 402 is properly formed, each capacitance C_{C} should be substantially identical.

If the differential signaling channel 300 is tested at a relatively low frequency compared to the frequency for which the channel 300 is designed to operate (e.g., <10 kilohertz, compared to several megahertz or gigahertz), then the coupling capacitances C_{C} can be ignored when developing an equivalent circuit model for the components shown in FIG. 6. This is because the impedance of the differential driver 310 should be very low compared to the impedances presented by the C_{S} and C_{C} capacitances. An equivalent circuit for the components shown in FIG. 6 therefore comprises a wired-AND pair of capacitances, C_{S}. See, FIG. 7.

Given the circuit model shown in FIG. 7, the driving of a differential waveform (i.e., complementary positive and negative waveforms representing a single waveform) over the channel 300 should result in no signal being induced in the capacitive sense plate 116. That is, the complementary positive and negative phases of the differential waveform should cancel each other out and induce no detectable signal in the sense plate 116. In reality, however, some amount of non-cancelable noise may be induced in one or both of the signal paths 302, 304; or there may be a small difference in the timings of the positive and negative signal phases that are respectively driven over the signal paths 302, 304; or there may be small physical variances between the signal paths 302, 304. As a result, it may be desirable to define a range of signals about zero that are indicative of a defect-free channel 300. For example, in one embodiment, a signal induced in the sense plate 116, having an amplitude that is between 0 and 0.1 times the amplitude of the differential waveform transmitted over the channel 300, may be considered indicative of a defect-free channel 300.

As defined herein, the “amplitude” of a differential waveform is the amplitude of either the positive or negative phase signal of the differential waveform.

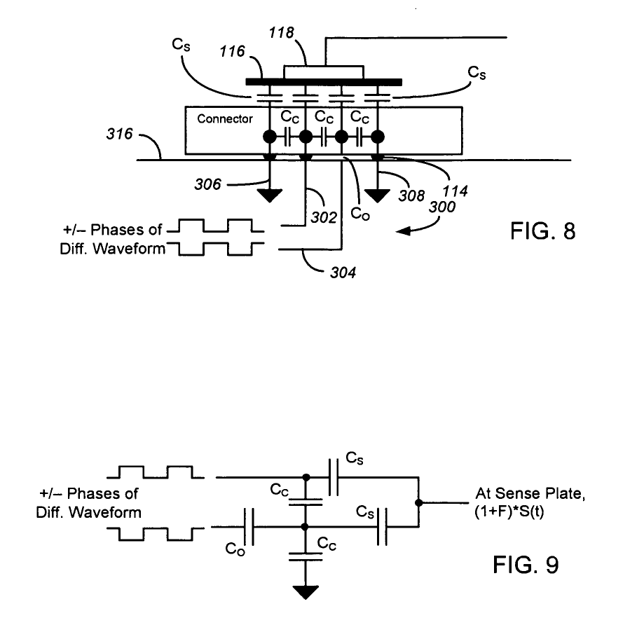

Now consider a channel defect comprised of an open in one of the signal paths 302, 304. FIGS. 8 & 9 illustrate such a case, where, by way of example, an open defect exists in the signal path carrying the negative phase of a differential waveform. Here, the small capacitances Cₛ and C_{C} still exist. See, FIG. 8. However, another capacitance C_{O} exists. The capacitance C_{O} represents an open created by, for example, a missing or defective solder joint between the connector 312 and the substrate 320.

An equivalent circuit 900 for the components shown in FIG. 8 is shown in FIG. 9. From the circuit 900, one can see that the positive phase of a differential waveform would be transmitted substantially in full to the sense plate 116 (via a small C_{S}), and part of the same signal would be coupled into sense plate 116 again, via a capacitive divider created by the capacitances C_{C}. A weak amount of the negative phase of the differential waveform would also be coupled to the sense plate 116, via a combination of C_{O} and C_{S} (although this small amount of coupling can be ignored).

Given the equivalent circuit 900, and after converting the capacitances C_{S} , C_{C} and C_{O} to respective impedances ZS, ZC and ZO, the signal R(t) seen at the sense plate 116 will be S(t)+F*S(t), or (1+F)*S(t), where S(t) is the positive phase of the differential waveform carried over the channel 300, and where “F” is defined by the function:

$$F = \frac{( ( 1 / {Z}_{C} ) - ( 1 / {Z}_{O} ) )}{( ( 1 / {Z}_{S} ) + ( 1 / {Z}_{C} ) + ( 1 / {Z}_{O} ) )} \qquad ( Equation 1 )$$

If an open exists in the signal path carrying the positive phase of a differential waveform, the equation for R(t) will be −(1+F)*S(t).

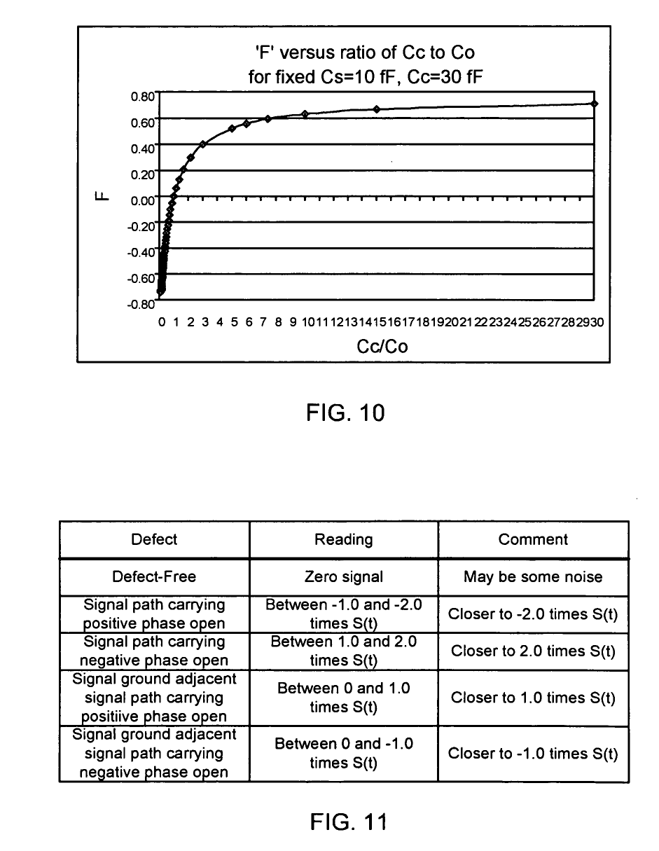

FIG. 10 shows a graph of “F” versus ratios of C_{C} to C_{O} ranging from roughly 0.1 to 30. By way of example, the graph assumes C_{S}=10 femtoFarads (fF), C_{C}=30 fF, and C_{O} ranges from 1 fF to over 200 fF. Although the values of “F” range from −1.0 to +1.0, and are negative for ratios of C_{C} to C_{O} less than 1.0, the ratio of C_{C} to C_{O} will typically be significantly greater than 1.0, so the value of “F” will most always be positive, and will range from 0 to +1.0. This means the amplitude of R(t) will range from |1| to |2| times the amplitude of S(t) if an open exists in one of the signal paths 302, 304 of the differential signaling channel 300. If the signal path carrying the negative phase of a differential waveform is open, R(t) will be negative, ranging from +1.0 to +2.0; and if the signal path carrying the positive phase of a differential waveform is open, R(t) will be positive, ranging from −1.0 to −2.0. See the table shown in FIG. 11.

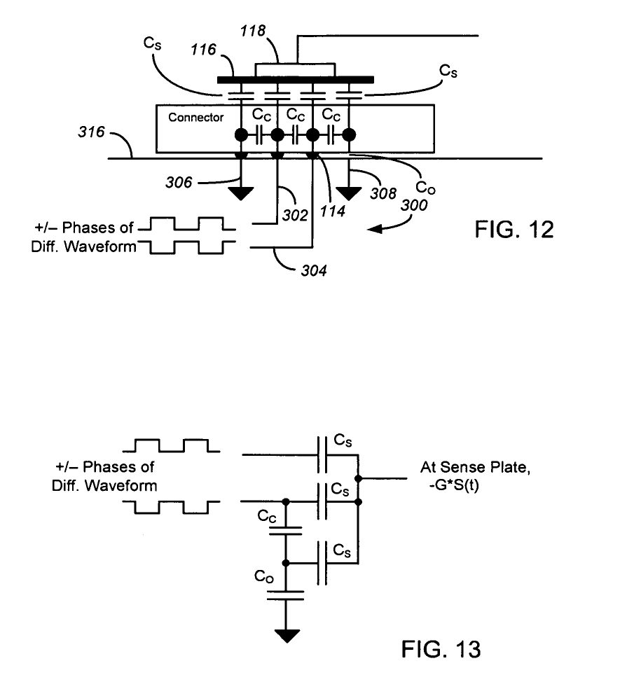

Now consider a channel defect comprised of an open in one of the signal grounds 306, 308. FIGS. 12 & 13 illustrate such a case, where, by way of example, an open defect exists in the signal ground adjacent the signal path carrying the negative phase of a differential waveform. Once again, the small capacitances C_{S} and C_{C} still exist. See, FIG. 12. However, a capacitance C_{O} now exists in the signal ground 308. The capacitance C_{O} represents an open created by, for example, a missing or defective solder joint between the connector 312 and the substrate 320.

An equivalent circuit 1300 for the components shown in FIG. 12 is shown in FIG. 13. From the circuit 1300, one can see that the positive and negative phases of a differential waveform would be transmitted substantially in full to the sense plate 116 (via small C_{S}'s), as in the defect-free case. However, a portion of the negative phase is also coupled into the sense plate 116 again, via a capacitive divider created by C_{C} and C_{O}.

Given the equivalent circuit 1300, the signal R(t) seen at the sense plate 116 will be S(t)−S(t)−G*S(t), or simply −G*S(t), where S(t) is the positive phase of the differential waveform carried over the channel 300, and where “G” is defined by the function:

$$G = \frac{{C}_{C}}{( {C}_{S} + {C}_{C} + {C}_{O} )} \qquad ( Equation 2 )$$

If an open exists in the signal ground adjacent the signal path carrying the positive phase of a differential waveform, the equation for R(t) will be G*S(t).

Assuming the values of C_{S}, C_{C} and C_{O} used to construct the graph shown in FIG. 10, or other reasonable values and ratios of C_{S}, C_{C} and C_{O}, the values of “G” will range from 0 to +1.0 (with “G” typically being closer to +1.0). This means the amplitude of R(t) will range from |0| to |1| times the amplitude of S(t) if an open exists in one of the signal grounds 306, 308 of the differential signaling channel 300. If the signal ground adjacent the signal path carrying the negative phase of a differential waveform is open, R(t) will be negative, ranging from 0 to −1.0; and if the signal ground adjacent the signal path carrying the positive phase of a differential waveform is open, R(t) will be positive, ranging from 0 to +1.0. See the table shown in FIG. 11.

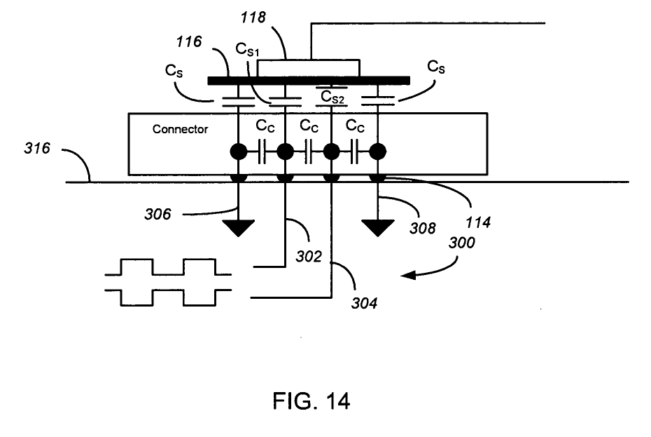

Although the apparatus discussed above is useful in testing the channel 300 for opens, a slight modification to the apparatus can enable the detection of shorts such as a “dead short” (i.e., a condition where both signal paths 302, 304 are shorted to ground). The modified apparatus is shown in FIG. 14 and comprises coupling the signal paths 302, 304 to the sense plate 116 via different but known capacitances C_{S1}, and C_{S2}. By doing this, the amplitude of the signal seen at the sense plate 116 in a defect-free case is non-zero, and a zero reading is indicative of a dead short of the channel 300. Although this changes the “F” and “G” in Equations (1) and (2), it does so in a known way that can be easily factored into these equations.

In one embodiment, one or both of the different but known capacitances C_{S1}, and C_{S2} may be formed as a dimple or recess in the sense plate 116. For example, if the sense plate 116 is formed of copper, a small amount of copper may be milled from the sense plate 116 above a pin of a connector to which the sense plate 116 couples, thereby unbalancing the coupling of the sense plate 116 to that pin (and the signal path 302 to which it is connected) as compared to a pin connected to the signal path 304.

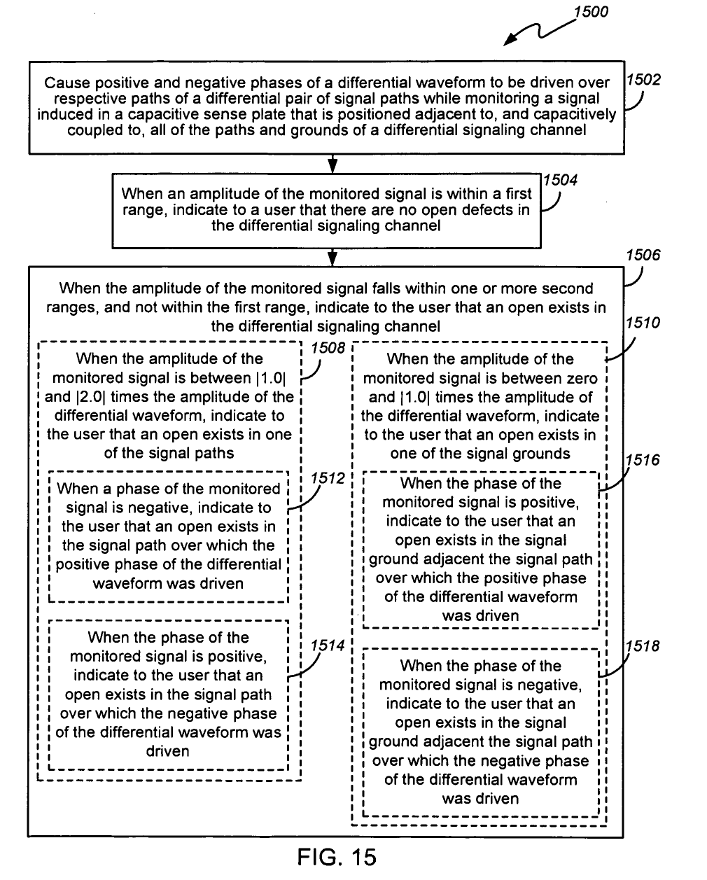

Given the above, FIG. 15 illustrates an exemplary method 1500 for testing a differential signaling channel 300. The method 1500 begins with a test system causing positive and negative phases of a differential waveform to be driven over respective paths 302, 304 of a differential pair of signal paths while monitoring a signal induced in a capacitive sense plate 116 (at block 1502). As shown in FIGS. 6, 8 & 12, the sense plate 116 is positioned adjacent to, and capacitively coupled to, all of the paths of the differential signaling channel 300.

When an amplitude of the monitored signal is within a first range, the method 1500 indicates to a user that there are no open defects in the signal paths or ground paths of the differential signaling channel (at block 1504). If the capacitances CS are substantially equal, the first range may be a range about zero. However, if the signal paths 302, 304 are coupled to the sense plate 116 via different capacitances C_{S1}, and C_{S2}, the first range may be a range that is offset from zero.

When the amplitude of the monitored signal falls within one or more second ranges, and not within the first range, the method 1500 indicates to the user that an open exists in one of the signal paths or ground paths (at block 1506).

The method 1500 is useful in that it enables a user to identify defects in a differential signaling channel, and thereby determine whether a device (e.g., a loaded PCB) is good or bad. By way of example, the remainder of this disclosure presumes that the capacitive sense plate 116 is coupled to all of the paths 302, 304 and grounds 306, 308 of the channel 300 via substantially equal capacitances C_{S}.

In some embodiments, the method 1500 may not only indicate that an open exists, but also indicate where the open exists. For example, when the amplitude of the monitored signal is between |1.0| and |2.0| times the amplitude of the differential waveform transmitted over the channel 300 (where the function |x| is the absolute value of the number x), the method 1500 may indicate to the user that an open exists in one of the channel's signal paths (at block 1508). The method 1500 may further include the steps of 1) when the phase of the monitored signal is negative, indicating to the user that an open exists in the signal path over which the positive phase of the differential waveform was driven (at block 1512), and 2) when the phase of the monitored signal is positive, indicating to the user that an open exists in the signal path over which the negative phase of the differential waveform was driven (at block 1514).

Although in theory, an open in a signal path should result in the amplitude of the signal monitored at the sense plate 116 being |1.0| to |2.0| times the amplitude of the differential waveform, open defects experienced by a particular type of device will typically fall within a much smaller range. As a result, it is believed useful to narrow the defective range as much as practicable, so that noise does not cause a defect to be indicated when none exists. To this end, it is believed that most opens are a result of poor solder joints between a connector and a PCB, and that most signal path opens of this type will result in the signal monitored at the sense plate 116 being |1.5| to |2.0| times the amplitude of the differential waveform.

Similarly to the above steps for identifying a signal path in which an open exists, the method 1500 may identify a signal ground in which an open exists. For example, when the amplitude of the monitored signal is between zero and |1.0| times the amplitude of the differential waveform transmitted over the channel 300, the method 1500 may indicate to the user that an open exists in one of the channel's grounds (at block 1510). The method 1500 may further include the steps of 1) when the phase of the monitored signal is positive, indicating to the user that an open exists in the ground adjacent the signal path over which the positive phase of the differential waveform was driven (at block 1516), and 2) when the phase of the monitored signal is negative, indicating to the user that an open exists in the ground adjacent the signal path over which the negative phase of the differential waveform was driven (at block 1518).

Once again, theory says that an open in a signal ground should result in the amplitude of the signal monitored at the sense plate 116 being zero to |1.0| times the amplitude of the differential waveform. However, open defects experienced by a particular type of device will typically fall within a much smaller range. As a result, it is believed useful to narrow the defective range as much as practicable, so that noise does not cause a defect to be indicated when none exists. To this end, it is believed that most opens are a result of poor solder joints between a connector and a PCB, and that most signal ground opens of this type will result in the signal monitored at the sense plate 116 being |0.5| to |1.0| times the amplitude of the differential waveform.

In one embodiment of the method 1500, the positive and negative phases of the differential waveform may be driven from a differential driver coupled to a boundary-scan chain. By way of example, the differential driver may be caused to drive the differential waveform in response to instructions complying with the Institute of Electrical and Electronics Engineers (IEEE) Standard 1149.1. Using a boundary-scan chain configured to implement Standard 1149.1, a given differential driver can be programmed to go high via a first data shift cycle, and low during the next data shift cycle. The length of time this takes is dependent on the TCK clock frequency and the total number of bits needed for shifting, plus 4 TCK cycles needed to return to the Shift-DR TAP state after passing out of the Update-DR state. If a boundary-scan chain comprises N boundary-scan cells, then the time to cycle a state of the differential driver is 2*(N+4)*(1/TCK). The frequency of TCK can be controlled (within the limits of frequency allowed in the chain) to match the period of this cycle to the period expected by the detector that monitors a capacitive sense plate 116 (typically ˜10 kHz). However, if N is too large, or if there are too many other restrictions on TCK, this may not be possible.

Instead of causing a differential waveform to be generated using IEEE Standard 1149.1 instructions, a differential waveform may be generated using IEEE Standard 1149.6 instructions. For example, the 1149.6 EXTEST_TRAIN instruction can cause a differential driver to produce a train of pulses at the frequency TCK/2 by staying in the Run-Test/Idle TAP state.

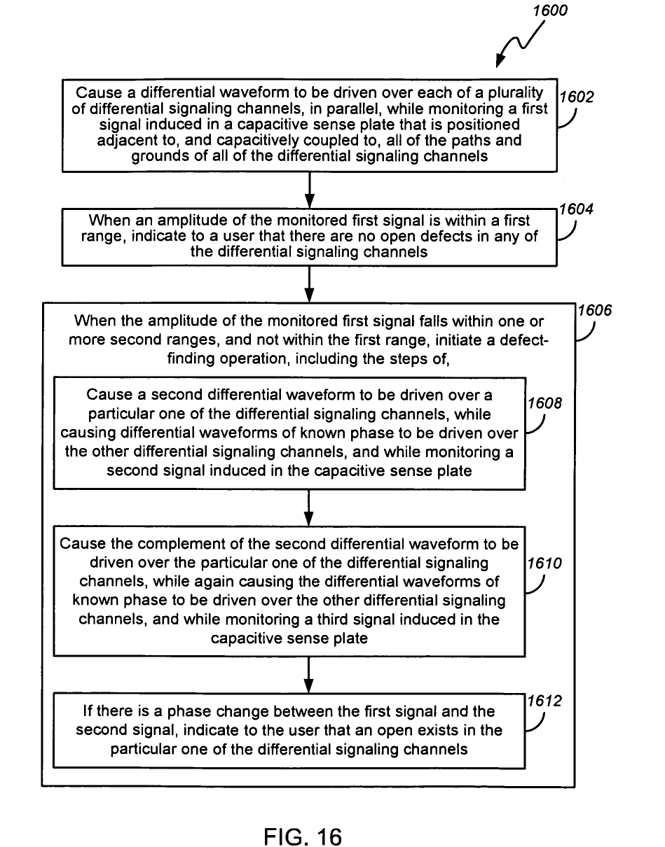

In contrast to FIG. 15, which illustrates a method 1500 for testing one differential signaling channel 300 at a time for open defects, FIG. 16 illustrates an exemplary method 1600 for testing a plurality of differential signaling channels 300 in parallel. The method 1600 begins with a test system causing a differential waveform to be driven over each of the differential signaling channels, in parallel (at block 1602). By “in parallel”, it is meant that a differential waveform is driven over each of the channels simultaneously, or at about the same time. In one embodiment, a common differential waveform may be driven over each of the channels. Alternately, different differential waveforms may be driven over at least two different channels.

While driving a differential waveform over each of the differential signaling channels, a first signal induced in a capacitive sense plate 116 is monitored (also at block 1602). The capacitive sense plate 116 is positioned adjacent to, and capacitively coupled to, all of the paths of all of the differential signaling channels.

When an amplitude of the monitored first signal is within a first range, the method 1600 indicates to a user that there are no open defects in any of the differential signaling channels (at block 1604). However, when the amplitude of the monitored first signal falls within one or more second ranges, and not within the first range, the method 1600 initiates a defect-finding operation (at block 1606).

The defect-finding operation includes the following steps. First, a differential waveform is caused to be driven over a particular one of the differential signaling channels, while causing differential waveforms of known phase to be driven over the other differential signaling channels, and while a second signal induced in the capacitive sense plate 116 is monitored (at block 1608). The complement of the differential waveform is then caused to be driven over the particular one of the differential signaling channels, while again causing the differential waveforms of known phase to be driven over the other differential signaling channels, and while a third signal induced in the capacitive sense plate 116 is monitored (at block 1610). If there is a phase change between the first signal and the second signal (i.e., from positive to negative, or from negative to positive), the method 1600 indicates to the user that an open exists in the particular one of the differential signaling channels (at block 1612).

The differential waveforms driven in steps 1602 and 1608 may be the same or different waveforms. In one embodiment of the method 1600, each of the differential waveforms driven over the differential signaling channels may be driven from one of a plurality of differential drivers coupled to a boundary-scan chain. By way of example, the differential drivers may be caused to simultaneously drive differential waveforms from a plurality of differential drivers by executing a boundary-scan instruction such as the EXTEST_TRAIN instruction defined by IEEE Standard 1149.6. The EXTEST_TRAIN instruction may also be used to test a particular one of the differential signaling channels.

Although the method 1600 may not work if a device has complementary pairs of defects (e.g., a first channel having an open in a signal path carrying the positive phase of a differential waveform, and a second channel having an open in a signal path carrying the negative phase of a differential waveform), the likelihood of such complementary defects is low.

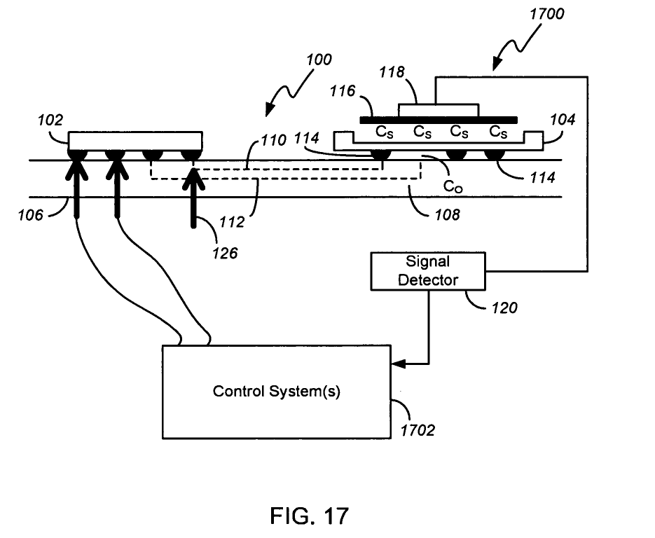

FIG. 17 illustrates exemplary apparatus 1700 for executing the method 1500 or 1600. Similarly to the apparatus shown in FIG. 1, the apparatus 1700 comprises a capacitive sense plate 116, buffer 118 and signal detector 120. In accord with various prior capacitive testing techniques, the sense plate 116 may be positioned in the connector 104; over a specially designed component containing engineered capacitances C_{S}, which component is inserted in the connector 104; or over a mission component (such as an IC that is intended to be inserted in the connector 104).

The apparatus 1700 further comprises at least one control system 1702. In one embodiment, the control system(s) 1702 couple to a test access port (TAP) of the IC 102 and program the TAP to cause one or more differential drivers of the IC 102 to drive differential waveforms to the connector 104. The control system(s) 1702 then receive the output of the signal detector 120 and indicate to a user whether open defects exist in one or more differential signaling channels.

The control system(s) 1702 may execute the method 1500 or 1600 by executing computer-readable code stored on computer-readable media. The computer-readable media may include, for example, any number or mixture of fixed or removable media (such as one or more fixed disks, random access memories (RAMs), read-only memories (ROMs), or compact discs), at either a single location or distributed over a network. The computer-readable code will typically comprise software, but could also comprise firmware or a programmed circuit.

The apparatus 1700 may further comprise test probes, such as probes 126, for contacting and grounding various nodes of the PCB 106 under control of the control system(s) 1702.

The apparatus 1700 may indicate to a user that opens exist, or do not exist, in various ways. For example, the control system(s) may cause a defect status to be provided via a graphical display, or may trigger an audible or visual (e.g., LED) alarm when a device under test is discovered to have a defect. A printed report including a part's defect status (e.g., pass/fail or defect location) may also be provided.

What is claimed is:

1. A method for testing a differential signaling channel having i) a differential pair of signal paths, and ii) a pair of signal grounds bounding the differential pair of signal paths, the method comprising:
causing positive and negative phases of a differential waveform to be driven over respective paths of the differential pair of signal paths while monitoring a signal induced in a capacitive sense plate that is positioned adjacent to, and capacitively coupled to, all of the paths and grounds of the differential signaling channel;
when an amplitude of the monitored signal is within a first range, indicating to a user that there are no open defects in the differential signaling channel; and
when the amplitude of the monitored signal falls within one or more second ranges, and not within the first range, indicating to the user that an open exists in the differential signaling channel.

2. The method of claim 1, wherein the capacitive sense plate is coupled to all of the paths and grounds via substantially equal capacitances, and wherein the first range is a range about zero.

3. The method of claim 1, wherein the capacitive sense plate is coupled to all of the paths and grounds via substantially equal capacitances, and wherein indicating to the user that an open exists in the differential signaling channel comprises:
when the amplitude of the monitored signal is between |1.0|]and |2.0| times the amplitude of the differential waveform, indicating to the user that an open exists in one of the signal paths.

4. The method of claim 3, wherein indicating to the user that an open exists in one of the signal paths comprises:
when a phase of the monitored signal is negative, indicating to the user that an open exists in the signal path over which the positive phase of the differential waveform was driven; and
when the phase of the monitored signal is positive, indicating to the user that an open exists in the signal path over which the negative phase of the differential waveform was driven.

5. The method of claim 1, wherein the capacitive sense plate is coupled to all of the paths and grounds via substantially equal capacitances, and wherein indicating to the user that an open exists in the differential signaling channel comprises:
when the amplitude of the monitored signal is between |1.5| and |2.0|times the amplitude of the differential waveform, indicating to the user that an open exists in one of the signal paths.

6. The method of claim 1, wherein the capacitive sense plate is coupled to all of the paths and grounds via substantially equal capacitances, and wherein indicating to the user that an open exists in the differential signaling channel comprises:
when the amplitude of the monitored signal is between zero and |1.0| times the amplitude of the differential waveform, indicating to the user that an open exists in one of the signal grounds.

7. The method of claim 1, wherein the capacitive sense plate is coupled to all of the paths and grounds via substantially equal capacitances, and wherein indicating to the user that an open exists in the differential signaling channel comprises:
when the amplitude of the monitored signal is between |0.5| and |1.0| times the amplitude of the differential waveform, indicating to the user that an open exists in one of the signal grounds.

8. The method of claim 7, wherein indicating to the user that an open exists in one of the signal grounds comprises:
when a phase of the monitored signal is positive, indicating to the user that an open exists in the signal ground adjacent the signal path over which the positive phase of the differential waveform was driven; and
when the phase of the monitored signal is negative, indicating to the user that an open exists in the signal ground adjacent the signal path over which the negative phase of the differential waveform was driven.

9. The method of claim 1, wherein the capacitive sense plate is positioned at a connector where the signal paths and signal grounds terminate.

10. The method of claim 1, further comprising:
causing the positive and negative phases of the differential waveform to be driven from a differential driver coupled to a boundary-scan chain.

11. The method of claim 10, wherein the capacitive sense plate is positioned at a connector where the signal paths and signal grounds terminate, wherein the differential driver is contained in an integrated circuit, wherein the integrated circuit is coupled to the connector via the differential signal channel, and wherein the integrated circuit is not mounted in the connector.

12. The method of claim 1, wherein the capacitive sense plate is coupled to the signal paths of the differential signaling channel via different but known capacitances, thereby causing the amplitude of the monitored signal to be non-zero when there are no open defects in the differential signaling channel.

13. A method for testing a device having a plurality of differential signaling channels, wherein each differential signaling channel has i) a differential pair of signal paths, and ii) a pair of signal grounds bounding the differential pair of signal paths, the method comprising:
causing a differential waveform to be driven over each of the differential signaling channels, in parallel, while monitoring a first signal induced in a capacitive sense plate that is positioned adjacent to, and capacitively coupled to, all of the paths and grounds of all of the differential signaling channels;
when an amplitude of the monitored first signal is within a first range, indicating to a user that there are no open defects in any of the differential signaling channels; and
when the amplitude of the monitored first signal falls within one or more second ranges, and not within the first range, initiating a defect-finding operation, including the steps of,
causing a second differential waveform to be driven over a particular one of the differential signaling channels, while causing differential waveforms of known phase to be driven over the other differential signaling channels, and while monitoring a second signal induced in the capacitive sense plate;
causing the complement of the second differential waveform to be driven over the particular one of the differential signaling channels, while again causing the differential waveforms of known phase to be driven over the other differential signaling channels, and while monitoring a third signal induced in the capacitive sense plate; and
if there is a phase change between the first signal and the second signal, indicating to the user that an open exists in the particular one of the differential signaling channels.

14. The method of claim 13, wherein the capacitive sense plate is coupled to all of the paths and grounds via substantially equal capacitances, and wherein the first range is a range about zero.

15. The method of claim 13, wherein causing a differential waveform to be driven over each of the differential signaling channels comprises driving a common differential waveform over each of the differential signaling channels.

16. The method of claim 13, wherein causing a differential waveform to be driven over each of the differential signaling channels comprises driving different differential waveforms over at least two of the differential signaling channels.

17. The method of claim 13, wherein all of the differential waveforms are a common differential waveform.

18. The method of claim 13, wherein the capacitive sense plate is positioned at a connector where the signal paths and signal grounds terminate.

19. The method of claim 13, wherein causing a differential waveform to be driven over each of the differential signaling channels comprises:
executing a boundary-scan instruction to cause a differential waveform to be simultaneously driven from a plurality of differential drivers coupled to the plurality of differential signaling channels.

20. The method of claim 13, wherein the capacitive sense plate is coupled to the signal paths of the differential signaling channel via different but known capacitances, thereby causing the amplitude of the monitored signal to be non-zero when there are no open defects in the differential signaling channel.

21. Apparatus for testing a differential signaling channel having i) a differential pair of signal paths, and ii) a pair of signal grounds bounding the differential pair of signal paths, the apparatus comprising:
a capacitive sense plate;
a signal detector, coupled to the capacitive sense plate; and
at least one control system configured to,
cause positive and negative phases of a differential waveform to be driven over respective paths of the differential pair of signal paths while i) the capacitive sense plate is positioned adjacent to, and capacitively coupled to, all of the paths and grounds of the differential signaling channel, and ii) the signal detector is configured to monitor a signal induced in the capacitive sense plate;
when an amplitude of the monitored signal is within a first range, indicate to a user that there are no open defects in the differential signaling channel; and
when the amplitude of the monitored signal falls within one or more second ranges, and not within the first range, indicate to the user that an open exists in the differential signaling channel.

22. The apparatus of claim 21, wherein the capacitive sense plate is coupled to all of the paths and grounds via substantially equal capacitances, and wherein the at least one control system is configured to indicate to the user that an open exists in the differential signaling channel by:
when the amplitude of the monitored signal is between |0.5| and |1.0| times the amplitude of the differential waveform, indicating to the user that an open exists in one of the signal grounds; and
when the amplitude of the monitored signal is between |1.0| and |2.0|times the amplitude of the differential waveform, indicating to the user that an open exists in one of the signal paths.

23. The apparatus of claim 22, wherein the at least one control system is further configured to:
indicate to the user that an open exists in one of the signal paths by i) when a phase of the monitored signal is negative, indicating to the user that an open exists in the signal path over which the positive phase of the differential waveform was driven, and ii) when the phase of the monitored signal is positive, indicating to the user that an open exists in the signal path over which the negative phase of the differential waveform was driven; and
indicate to the user that an open exists in one of the signal grounds by i) when a phase of the monitored signal is positive, indicating to the user that an open exists in the signal ground adjacent the signal path over which the positive phase of the differential waveform was driven, and ii) when the phase of the monitored signal is negative, indicating to the user that an open exists in the signal ground adjacent the signal path over which the negative phase of the differential waveform was driven.

24. The apparatus of claim 22, wherein the capacitive sense plate is coupled to the signal paths of the differential signaling channel via different but known capacitances, thereby causing the amplitude of the monitored signal to be non-zero when there are no open defects in the differential signaling channel.

25. Apparatus for testing a device having a plurality of differential signaling channels, wherein each differential signaling channel has i) a differential pair of signal paths, and ii) a pair of signal grounds bounding the differential pair of signal paths, the apparatus comprising:
a capacitive sense plate;
a signal detector, coupled to the capacitive sense plate; and
at least one control system configured to,
cause a differential waveform to be driven over each of the differential signaling channels, in parallel, while i) the capacitive sense plate is positioned adjacent to, and capacitively coupled to, all of the paths and grounds of all of the differential signaling channels, and ii) the signal detector is configured to monitor a first signal induced in the capacitive sense plate;
when an amplitude of the monitored first signal is within a first range, indicate to a user that there are no open defects in any of the differential signaling channels; and
when the amplitude of the monitored first signal falls within one or more second ranges, and not within the first range, then initiate a defect-finding operation, including the steps of,
driving a second differential waveform over a particular one of the differential signaling channels, while causing differential waveforms of known phase to be driven over the other differential signaling channels, and while the signal detector monitors a second signal induced in the capacitive sense plate;
driving the complement of the second differential waveform over the particular one of the differential signaling channels, while again causing the differential waveforms of known phase to be driven over the other differential signaling channels, and while the signal detector monitors a third signal induced in the capacitive sense plate; and
if there is a phase change between the first signal and the second signal, indicating to the user that an open exists in the particular one of the differential signaling channels.

26. The apparatus of claim 25, wherein the at least one control system is further configured to initiate execution of a boundary-scan instruction that causes the first differential waveform to be simultaneously driven from a plurality of differential drivers coupled to the plurality of differential signaling channels.

27. The apparatus of claim 25, wherein the capacitive sense plate is coupled to the signal paths of the differential signaling channel via different but known capacitances, thereby causing the amplitude of the monitored signal to be non-zero when there are no open defects in the differential signaling channel.
